(19) United States
(12) Patent Application Publication
(10) Pub. No.: US 2025/0380405 A1
(43) Pub. Date: Dec. 11, 2025

(54) METHOD OF MANUFACTURING SEMICONDUCTOR STRUCTURE INCLUDING NITROGEN TREATMENT AND SEMICONDUCTOR STRUCTURE THEREOF

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/765,124

(22) Filed: Jul. 5, 2024

Related U.S. Application Data
(62) Division of application No. 18/736,843, filed on Jun. 7, 2024.

(51) Int. Cl. H10B 12/00

(52) U.S. Cl. CPC H10B 12/34; H10B 12/053; H10B 12/50

(57) ABSTRACT

A semiconductor structure includes a substrate, a residual film, an oxide layer, a plurality of word lines, and a plurality of contacts. A plurality of pillars is formed in an array region of the substrate. A top surface of each of the plurality of pillars is a substantially planar surface. The residual film is partially disposed on sidewalls of the pillars proximal to the top surfaces of the pillars. The oxide layer surrounds each of the pillars. The word lines are respectively disposed in the pillars. Each of the contacts is disposed between two adjacent pillars. Each of the word lines includes a dielectric layer, a lower electrode structure, and an upper electrode structure. A dielectric layer is disposed in each of the pillars, a lower electrode structure is disposed on the dielectric layer, and an upper electrode structure is disposed on the lower electrode structure.

### CROSS-REFERENCE TO RELATED APPLICATION

This application is a divisional application of U.S. Non-Provisional application Ser. No. 18/736,843 filed Jun. 7, 2024, which is incorporated herein by reference in its entirety.

### TECHNICAL FIELD

The present disclosure relates to a method of manufacturing a semiconductor structure, and to a semiconductor structure formed by the method. In particular, the present disclosure relates to a method including a nitrogen treatment to prevent rounding from occurring during formation of an oxide material.

### DISCUSSION OF THE BACKGROUND

Semiconductor devices are used in a variety of electronic applications, such as personal computers, cellular phones, digital cameras, and other electronic equipment. The semiconductor devices are typically fabricated by sequentially depositing insulating or dielectric layers, conductive layers, and semiconductive layers of material over a semiconductor substrate, and patterning the various material layers using lithography to form circuit components and elements thereon. As the semiconductor industry has progressed into advanced technology process nodes in pursuit of greater device density, higher performance, and lower costs, challenges of precise control of configuration of an element have arisen.

This Discussion of the Background section is provided for background information only. The statements in this Discussion of the Background are not an admission that the subject matter disclosed in this Discussion of the Background section constitute prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor structure. The semiconductor structure includes a substrate, including a plurality of pillars in an array region of the substrate, wherein a top surface of each of the plurality of pillars is a substantially planar surface; a residual film, partially disposed on sidewalls of the pillars proximal to the top surfaces of the pillars; an oxide layer, surrounding each of the pillars; a plurality of word lines, disposed in the pillars respectively; and a plurality of contacts, each disposed between two adjacent pillars; wherein each of the word lines includes a dielectric layer, a lower electrode structure, and an upper electrode structure; and wherein a plurality of dielectric layers are respectively correspondingly disposed in the pillars, a plurality of lower electrode structures are disposed on the dielectric layers, and a plurality of upper electrode structures are disposed on the lower electrode structures.

Another aspect of the present disclosure provides a semiconductor structure. The semiconductor structure includes a substrate, including a plurality of pillars in an array region of the substrate, wherein a top surface of each of the plurality of pillars is a substantially planar surface; a residual film, partially disposed on sidewalls of the pillars proximal to the top surfaces of the pillars; an oxide layer, surrounding each of the pillars; a plurality of word lines, respectively disposed in the pillars; and a plurality of contacts, each disposed between two adjacent pillars; wherein each of the word lines includes a plurality of word line layers disposed in the substrate and surrounded by dielectric liners, and a plurality of insulative plugs respectively disposed in the substrate and extending into the word line layers.

Another aspect of the present disclosure provides a method of manufacturing a semiconductor structure. The method includes providing a substrate, wherein the substrate includes a plurality of pillars, and a top surface of each of the plurality of pillars is a substantially planar surface; performing a nitrogen treatment on the pillars; forming an oxide layer over the substrate conformal to the plurality of pillars; forming a first dielectric layer among the pillars; forming a second dielectric layer over the plurality of pillars, wherein a top surface of the second dielectric layer is a substantially planar surface; forming a plurality of first trenches in the plurality of pillars and a plurality of second trenches in the first dielectric layer among the pillars; and forming a word line in each of the first trenches, wherein each of the word lines includes a dielectric layer, a lower electrode structure, and an upper electrode structure; wherein a dielectric layer is disposed in each of the pillars, a lower electrode structure is disposed on the dielectric layer, and an upper electrode structure is disposed on the lower electrode structure.

Another aspect of the present disclosure provides a method of manufacturing a semiconductor structure. The method includes providing a substrate, wherein the substrate includes a plurality of pillars, and a top surface of each of the pillars is a substantially planar surface; performing a nitrogen treatment on the pillars; forming an oxide layer over the substrate conformal to the plurality of pillars; forming a first dielectric layer among the pillars; forming a second dielectric layer over the plurality of pillars, wherein a top surface of the second dielectric layer is a substantially planar surface; forming a plurality of first trenches in the plurality of pillars and a plurality of second trenches in the first dielectric layer among the pillars; and forming a word line in each of the first trenches, wherein each of the word lines includes a plurality of word line layers disposed in the substrate and surrounded by dielectric liners, and a plurality of insulative plugs disposed in the substrate and extending into the word line layers, respectively.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

A more complete understanding of the present disclosure may be derived by referring to the detailed description and claims. The disclosure should also be understood to be coupled to the figures' reference numbers, which refer to similar elements throughout the description.

FIG. 1 is a schematic 3D diagram of an intermediate stage in formation of a semiconductor structure in accordance with some embodiments of the present disclosure.

FIG. 2 is a schematic 3D diagram of an intermediate stage in formation of a semiconductor structure in accordance with some embodiments of the present disclosure.

FIG. 3 is an enlarged diagram of a portion of the intermediate stage in the formation of the semiconductor structure shown in FIG. 2 in accordance with some embodiments of the present disclosure.

FIGS. 4 to 21 are cross-sectional diagrams along a line A-A′ shown in FIG. 2 of intermediate stages in the formation of the semiconductor structure in accordance with some embodiments of the present disclosure.

FIG. 22 is a flow diagram illustrating a method of manufacturing a semiconductor structure in accordance with some embodiments of the present disclosure.

FIGS. 23 to 26 are cross-sectional diagrams along the line A-A′shown in FIG. 2 of intermediate stages in the formation of the semiconductor structure in accordance with some embodiments of the present disclosure.

FIG. 27 is a flow diagram illustrating a method of manufacturing a semiconductor structure in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It shall be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

As the semiconductor industry has progressed into advanced technology process nodes in pursuit of greater device density, it is important to reach an advanced precision of control of a configuration of elements formed in a device. For instance, a configuration of a silicon pillar of a substrate in an array region of a memory device can be affected by operations performed during subsequent processes. When undesired oxidation of the silicon pillar occurs, the configuration of the silicon pillar is changed. Rounding of edges or formation of an uneven surface of the silicon pillar results in a reduction of a contact area between the silicon pillar and a landing pad, and an electrical disconnection or high electrical resistance between the silicon pillar and the landing pad occurs. The present disclosure relates to a method for manufacturing a semiconductor structure. In particular, the method of the present disclosure is able to provide a planar surface of a silicon pillar so as to avoid issues of electrical disconnection and high electrical resistance. A performance and a product yield of a device formed according to the method can be thereby improved.

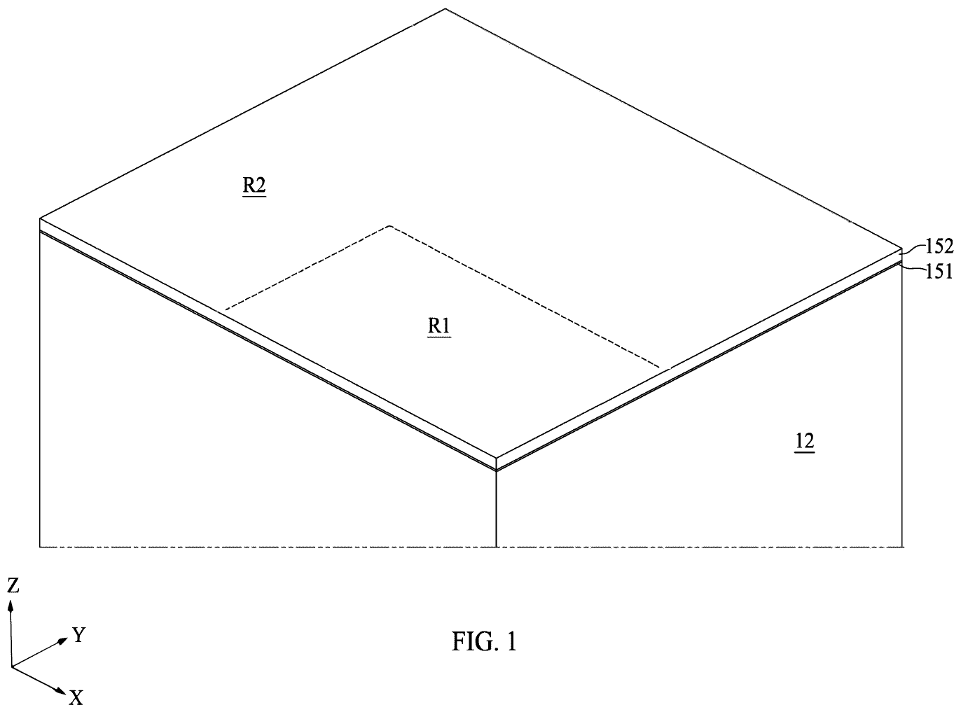

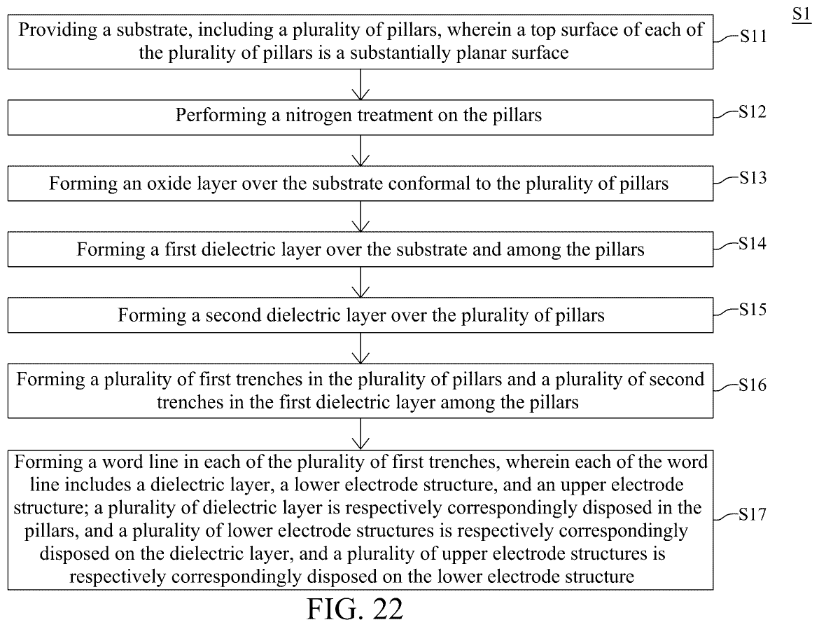

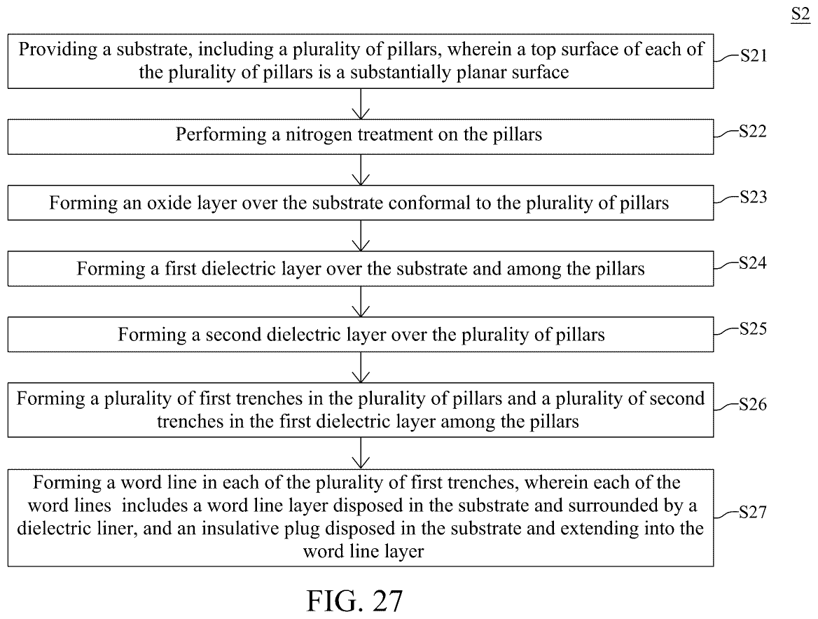

FIGS. 1 to 21 are schematic diagrams from different perspectives illustrating various fabrication stages according to one or more methods for manufacturing a semiconductor structure in accordance with some embodiments of the present disclosure. The stages shown in FIGS. 1 to 21 are also illustrated schematically in process flows of a method S1 in FIG. 22 and a method S2 in FIG. 27.

FIG. 22 is a flow diagram illustrating a method S1 for manufacturing a semiconductor device in accordance with some embodiments of the present disclosure. The method S1 includes a number of operations (S11, S12, S13, S14, S15, S16 and S17) and the description and illustration are not deemed as a limitation to the sequence of the operations. In the operation S11, a substrate is provided, wherein the substrate includes a plurality of pillars, and a top surface of each of the plurality of pillars is a substantially planar surface. In the operation S12, a nitrogen treatment is performed on the pillars. In the operation S13, an oxide layer is formed over the substrate conformal to the plurality of pillars. In the operation S14, a first dielectric layer is formed over the substrate and among the pillars. In the operation S15, a second dielectric layer is formed over the plurality of pillars. In the operation S16, a plurality of first trenches are formed in the plurality of pillars and a plurality of second trenches are formed in the first dielectric layer among the pillars. In the operation S17, the plurality of first trenches are filled with a conductive material to form a plurality of word lines, wherein each of the word lines includes a dielectric layer, a lower electrode structure, and an upper electrode structure; a plurality of dielectric layers are respectively correspondingly disposed in the pillars, wherein a lower electrode structure is disposed on the dielectric layer in each of the pillars, and an upper electrode structure is disposed on each of the lower electrode structures. It should be noted that the operations of the method S1 may be rearranged or otherwise modified within the scope of the various aspects. Additional processes may be provided before, during, and after the method S1, and some other processes may be only briefly described herein. Thus, other implementations are possible within the scope of the various aspects described herein.

Referring to FIG. 1, one or more dielectric layers are formed over a substrate 12. In some embodiments, prior to the formation of the dielectric layer(s), the substrate 12 is provided, received, or formed.

In some embodiments, the substrate 12 may have a multilayer structure, or the substrate 12 may include a multilayer compound semiconductor structure. In some embodiments, the substrate 12 includes semiconductor devices, electrical components, electrical elements, or a combination thereof. In some embodiments, the substrate 12 includes transistors or functional units of transistors. In some embodiments, the substrate 12 includes active components, passive components, and/or conductive elements. The active components may include a memory die (e.g., a dynamic random-access memory (DRAM) die, a static random-access memory (SRAM) die, etc.), a power management die (e.g., a power management integrated circuit (PMIC) die), a logic die (e.g., a system-on-a-chip (SoC), a central processing unit (CPU), a graphics processing unit (GPU), an application processor (AP), a microcontroller, etc.), a radio frequency (RF) die, a sensor die, a micro-electro-mechanical-system (MEMS) die, a signal processing die (e.g., a digital signal processing (DSP) die), a front-end die (e.g., an analog front-end (AFE) die) or other active components. Each of the active components may include multiple transistors. The transistors can include planar transistors, multi-gate transistors, gate-all-around field-effect transistors (GAAFET), fin field-effect transistors (FinFET), vertical transistors, nanosheet transistors, nanowire transistors, or a combination thereof. The passive components may include a capacitor, a resistor, an inductor, a fuse or other passive components. The conductive elements may include metal lines, metal islands, conductive vias, contacts or other conductive elements.

The active components, passive components, and/or conductive elements as mentioned above can be formed in and/or over a semiconductor substrate. The semiconductor substrate may be a bulk semiconductor, a semiconductor-on-insulator (SOI) substrate, or the like. The semiconductor substrate can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Si:Ge feature in which Si and Ge compositions change from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy.

For a purpose of simplicity, the substrate 12 depicted in FIG. 1 can be only a topmost portion of a multilayer structure of the substrate 12. The substrate 12 may include an array region R1 and a peripheral region R2 surrounding the array region R1. In some embodiments, the active components or the transistors are mostly formed in the array region R1, and the peripheral region R2 is for circuit routing and may include passive components. In some embodiments, the substrate 12 includes a silicon material.

Memory cells or devices (not shown) may be formed in the array region R1 of the substrate 12. For a purpose of illustration, the figures show a portion of the substrate 12 above the memory cells or memory devices. Bit line (BL) metals and word line (WL) metals (not shown) are formed during subsequent processing over and in the topmost portion of the substrate 12 shown in FIG. 1.

A dielectric layer 151 and a dielectric layer 152 can be formed over the substrate 12. In some embodiments, the dielectric layer 151 and the dielectric layer 152 include different dielectric materials. In some embodiments, the dielectric materials include silicon oxide (SiOₓ), silicon nitride (SiₓN_{y}), silicon oxynitride (SiON), or a combination thereof. In some embodiments, the dielectric materials include a high-k dielectric material. The high-k dielectric material may have a dielectric constant (k value) greater than 4. The high-k dielectric material may include zirconium dioxide (ZrO₂), hafnium oxide (HfO₂), aluminum oxide (Al₂O₃), yttrium oxide (Y₂O₃), lanthanum oxide (La₂O₃), silicates of one or more of ZrO₂, HfO₂, Al₂O₃, Y₂O₃ and La₂O₃, aluminates of one or more of ZrO₂, HfO₂, Y₂O₃ and La₂O₃, tantalum oxide (Ta₂O₅), barium titanate (BaTiO₃), titanium dioxide (TiO₂), cerium oxide (CeO₂), lanthanum aluminum oxide (LaAlO₃), lead titanate (PbTiO₃), strontium titanate (SrTiO₃), lead zirconate (PbZrO₃), tungsten oxide (WO₃), bismuth silicon oxide (Bi₄Si₂O₁₂), barium strontium titanate (BST) (Ba₁₋ₓSrₓTiO₃), PMN (PbMgₓNb₁₋ₓO₃), PZT (PbZrₓTi₁₋ₓO₃), PZN (PbZnₓNb₁₋ₓO₃), PST (PbScₓTa₁₋ₓO₃), hafnium zirconium oxide (HfₓZr_{y}O_{z}), hafnium zirconium aluminum oxide (Hf_{w}ZrₓAl_{y}O_{z}), lithium oxide (Li₂O), hafnium silicon oxide (HfSiO₄), strontium oxide (SrO), scandium oxide (Sc₂O₃), molybdenum trioxide (MoO₃), barium oxide (BaO), or a combination thereof. Other suitable materials are within the contemplated scope of this disclosure.

In some embodiments, the dielectric layers 151 and 152 include different oxide materials listed above. In some embodiments, the dielectric layers 151 and 152 are formed by different depositions. In some embodiments, a thickness of the dielectric layer 151 is less than a thickness of the dielectric layer 152. The dielectric layers 151 and 152 may function to protect the substrate 12 from a patterning operation that is subsequently performed. The two dielectric layers 151 and 152 are shown for a purpose of illustration. In alternative embodiments, only one dielectric layer is formed over the substrate 12. In other alternative embodiments, more than two dielectric layers are formed over the substrate 12.

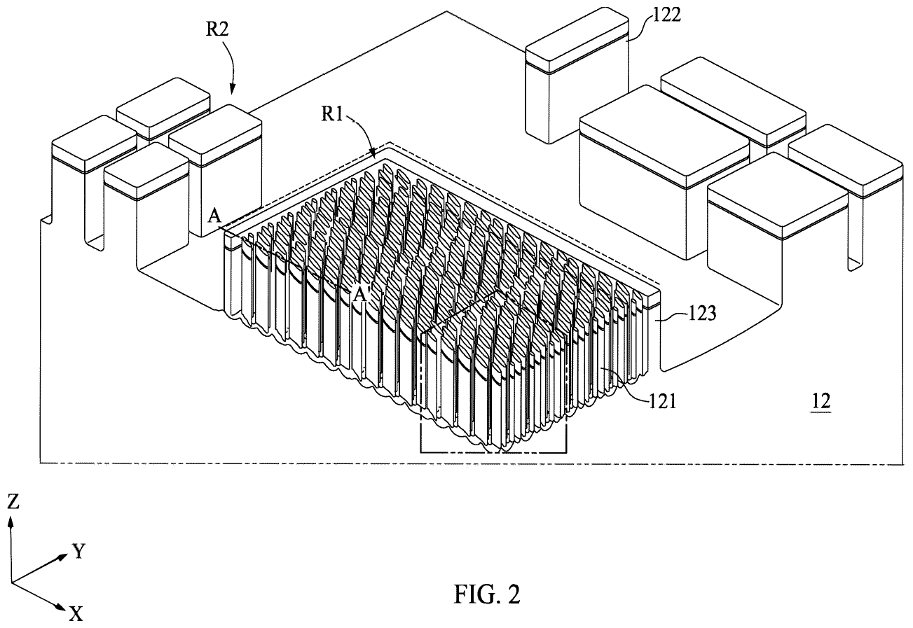

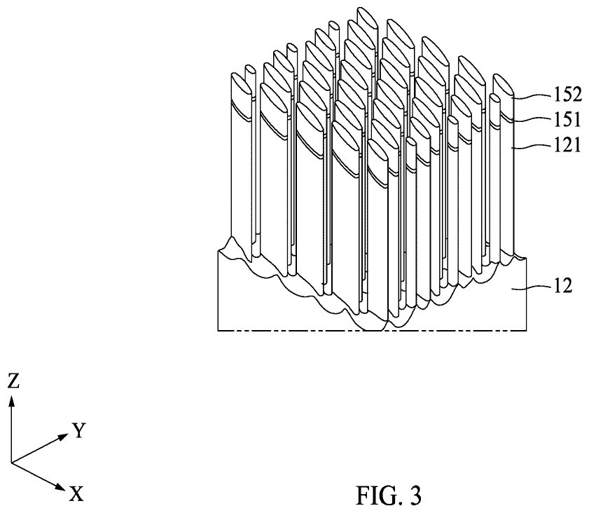

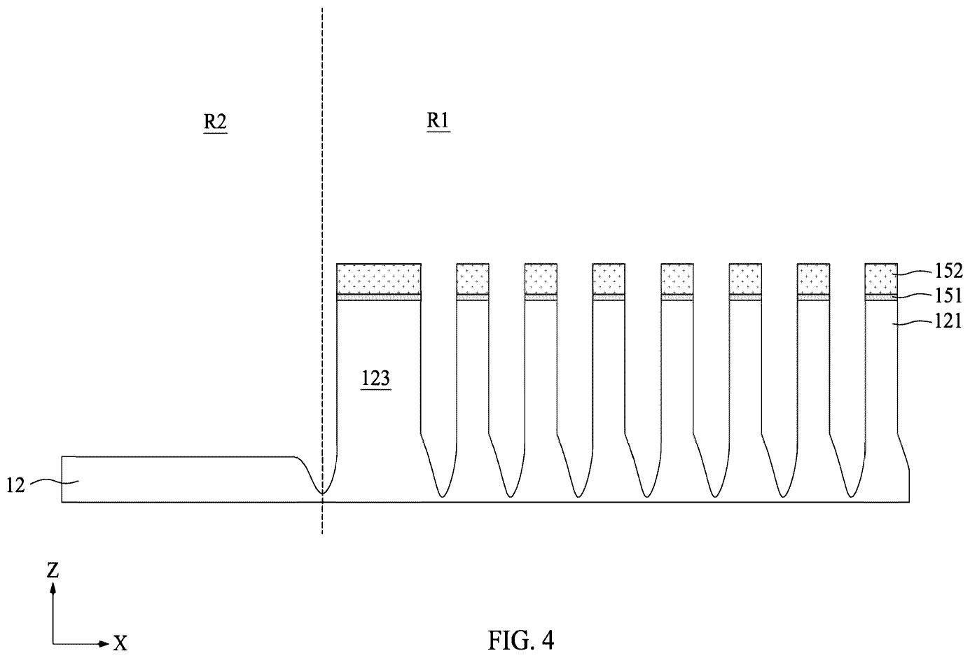

Referring to FIGS. 2, 3 and 4, FIG. 2 is a schematic 3D diagram, FIG. 3 is an enlarged view of a portion of the array region RI indicated by a dotted line in FIG. 2, and FIG. 4 is a schematic cross-sectional diagram along a line A-A′ in FIG. 2 at a stage of one or more methods for manufacturing a semiconductor structure in accordance with some embodiments of the present disclosure. A patterning operation may be performed on the dielectric layers 151 and 152 and the substrate 12. In some embodiments, multiple pillar-like silicon portions 121 are formed in the array region R1. In some embodiments, multiple island-like silicon portions 122 are formed in the peripheral region R2. In some embodiments, a strip-like silicon portion 123 is formed surrounding the pillar-like silicon portions 121 in the array region R1. In some embodiments, each of the dielectric layers 151 and 152 is patterned into portions. In some embodiments, each pillar-like silicon portion 121 has a portion of the dielectric layer 151 and a portion of the dielectric layer 152 disposed thereon. In some embodiments, each island-like silicon portion 122 has a portion of the dielectric layer 151 and a portion of the dielectric layer 152 disposed thereon. In some embodiments, the strip-like silicon portion 123 has a portion of the dielectric layer 151 and a portion of the dielectric layer 152 disposed thereon.

The strip-like silicon portion 123 may extend along a periphery of the array region R1. The strip-like silicon portion 123 can be a dummy structure in a memory device formed in subsequent processing. In some embodiments, the strip-like silicon portion 123 is not considered a part of an array of memory cells of the memory device. In some embodiments, the silicon portion 123 is for a purpose of definition of an area of the array of memory cells of the memory device. For a purpose of illustration, the strip-like silicon portion 123 is defined within the array region R1. However, in alternative embodiments, the strip-like silicon portion 123 is defined in the peripheral region R2, and the array region RI includes only the pillar-like silicon portions 121.

The patterning operation performed on the dielectric layers 151 and 152 and the substrate 12 may include one or more etching operations. In some embodiments, the dielectric layers 151 and 152 and the substrate 12 are patterned sequentially by different etching operations. In some embodiments, one or more etching operations having a high selectivity to the dielectric materials of the dielectric layer 151 and/or the dielectric layer 152 and a low selectivity to a silicon material of the substrate 12 are performed. The dielectric layers 151 and 152 can be patterned by one or more etching operations depending on the dielectric materials of the dielectric layers 151 and 152. A conventional patterning method can be applied, and is not limited herein. In some embodiments, an etching operation having a low selectivity to the silicon material of the substrate 12 is performed next. In some embodiments, the dielectric layers 151 and 152 and the substrate 12 are patterned concurrently by one etching operation. In some embodiments, a non-selective etching operation is performed, and the dielectric layers 151 and 152 and the substrate 12 are patterned concurrently by one etching operation.

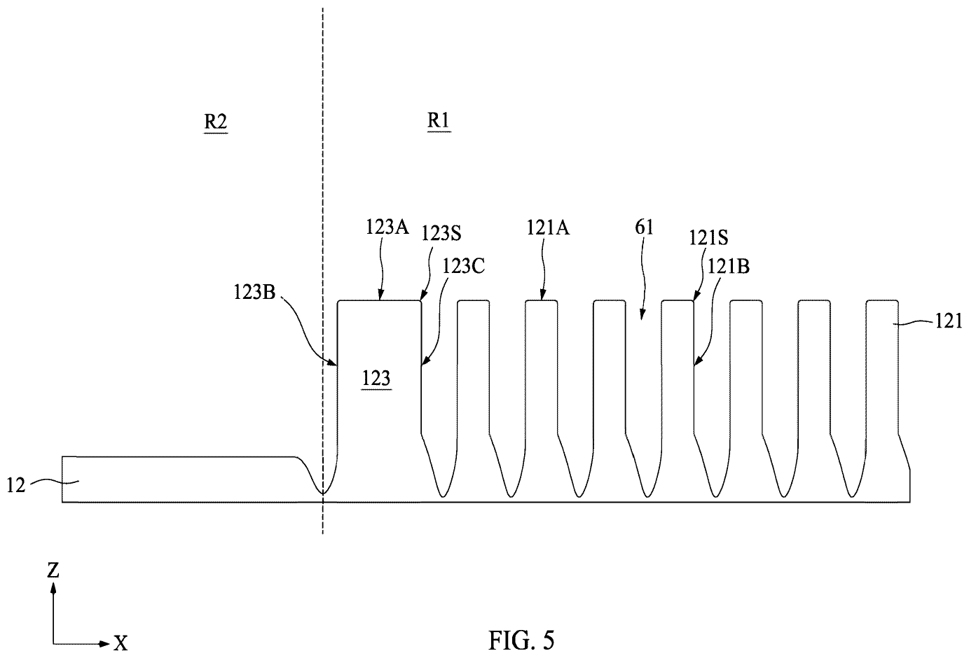

FIGS. 5 to 21 are schematic cross-sectional diagrams along the line A-A′ in FIG. 2 at a stage of the method S1 or the method S2 in accordance with some embodiments of the present disclosure. For a purpose of illustration, the schematic cross-sectional diagrams shown in FIGS. 5 to 21 are focused on the array region R1. However, such illustration is not intended to limit the present disclosure.

Similar or same operations can be performed concurrently in the peripheral region R2. In some embodiments, all operations or processes described below are performed concurrently in the array region R1 and the peripheral region R2. In some embodiments, all operations or processes described below are performed on an entirety of the substrate 12.

Referring to FIG. 5, the dielectric layers 151 and 152 are removed after the formation of the pillar-like silicon portions 121 and the island-like silicon portions 122. Similar to the process described above, one or more etching operations may be performed depending on the materials of the dielectric layers 151 and 152. The one or more etching operations for removing the dielectric layers 151 and 152 should include a low selectivity to the silicon material of the substrate 12. In some embodiments, a top surface 121A of each of the pillar-like silicon portions 121 is exposed after the removal of the dielectric layers 151 and 152. In some embodiments, the top surface 121A is a substantially planar surface. Each of the pillar-like silicon portions 121 may have a sidewall 121B. In some embodiments, a corner 121S of the pillar-like silicon portion 121 is a sharp corner. In some embodiments, the corner 121S is an intersection of the top surface 121A and the sidewall 121B. A plurality of spaces 61 are defined between the sidewalls 121B of the pillar-like silicon portions 121 in the array region R1.

In some embodiments, a top surface 123A of the strip-like silicon portions 123 is exposed after the removal of the dielectric layers 151 and 152. In some embodiments, the top surface 123A is a substantially planar surface. In some embodiments, the top surfaces 121A and 123A of the silicon portions 121 and 123 are substantially coplanar. In some embodiments, the top surfaces 121A and 123A of the silicon portions 121 and 123 together define a top surface 12A of the substrate 12. In some embodiments, the top surface 12A is a substantially planar surface.

The strip-like silicon portion 123 may have two opposite sidewalls 123B and 123C. In some embodiments, the sidewall 123B faces toward the peripheral region R2 and away from the pillar-like silicon portions 121. In some embodiments, a corner 123S of the strip-like silicon portion 123 is a sharp corner. In some embodiments, the corner 123S is an intersection of the top surface 123A and the sidewall 123B or 123C. In some embodiments, a distance between the strip-like silicon portion 123 and the pillar-like silicon portion 121 is substantially equal to a distance between two adjacent pillar-like silicon portions 121. The respective step is illustrated as the operation S11 in the method S1 shown in FIG. 22.

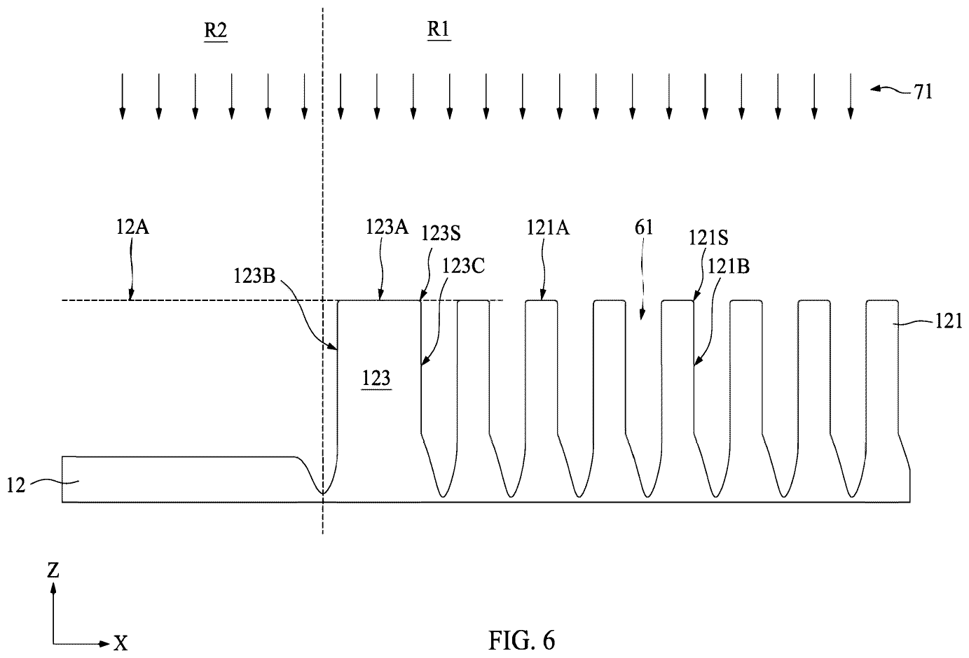

Referring to FIG. 6, a nitrogen treatment 71 is performed on the substrate 12. In some embodiments, the nitrogen treatment 71 is performed on an entirety of the substrate 12. In some embodiments, the nitrogen treatment 71 is performed in the array region R1 and the peripheral region R2 of the substrate 12. In some embodiments, the nitrogen treatment 71 is to provide nitrogen to the substrate 12. The nitrogen from the nitrogen treatment 71 can react with silicon of the substrate 12. In some embodiments, the nitrogen from the nitrogen treatment 71 is bonded to a portion of an exposed surface of the substrate 12. In some embodiments, the exposed surface of the substrate 12 is partially nitrided by the nitrogen treatment 71. In some embodiments, the nitrogen treatment 71 is referred to as a nitridation. The nitrogen treatment 71 is for a purpose of protecting the silicon portions 121 from oxidation during subsequent processing. It should be noted that the use of nitrogen in the treatment 71 is presented as an example for a purpose of illustration, and other elements can be used instead of nitrogen to achieve a same result. The respective step is illustrated as the operation S12 in the method S1 shown in FIG. 22.

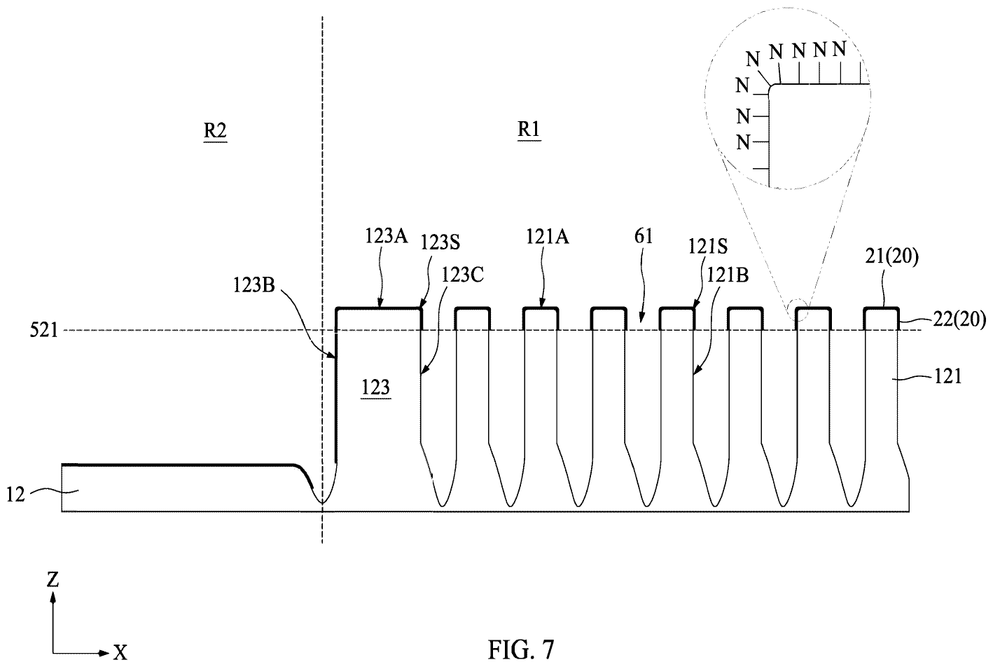

Referring to FIG. 7, FIG. 7 shows a structure resulting from the nitrogen treatment 71. The nitrogen from the nitrogen treatment 71 shown in FIG. 6 remains on or is bonded to the substrate 12 as shown in an enlarged view of a portion of the silicon portion 121 indicated by a dashed circle. In some embodiments, the residual nitrogen on the substrate 12 forms a protective film or a residual film capping each of the silicon portions 121. For a purpose of illustration, the residual nitrogen on the substrate 12 is referred to as a residual film 20. The residual film 20 may also be formed in the peripheral region R2.

The residual film 20 at least covers the top surfaces 121A and the corners 121S of the silicon portions 121. In some embodiments, the residual film 20 covers an entirety of the top surfaces 121A of the silicon portions 121. In some embodiments, the residual film 20 covers an entirety of the top surfaces 123A of the silicon portions 123. In some embodiments, the residual film 20 extends below the top surface 121A or 123A of the silicon portions 121 or 123. However, due to small spacing between the pillar-like silicon portions 121, the residual film 20 may not be able to cover an entirety of a sidewall 121B of the pillar-like silicon portion 121 along a vertical direction (i.e., the Z direction). In other words, a width of the space 61 may not be sufficient to let the nitrogen of the nitrogen treatment 71 shown in FIG. 7 reach the entirety of the sidewall 121B of the pillar-like silicon portion 121 along the vertical direction.

The residual film 20 may include a horizontal portion 21 disposed on the top surface 121A of the silicon portions 121, and a vertical portion 22 disposed on an upper portion of each of the sidewalls 121B of the silicon portions 121. In some embodiments, the upper portion of the sidewall 121B is surrounded by the vertical portion 22 of the residual film 20. In some embodiments, a top portion of each of the sidewalls 121B of the silicon portions 121 is exposed through the residual film 20. For a purpose of illustration, a dashed line 521 is depicted in FIG. 7 to indicate a horizontal level of a bottom of the residual film 20 capping the silicon portions 121 (i.e., a horizontal level of intersections between the upper portion and a lower portion of the sidewalls 121B).

A depth of the vertical portion 22 of the residual film 20 on a silicon portion 121, 122 or 123 depends on a distance from an adjacent silicon portion 121, 122 or 123. For example, a depth of the vertical portion 22 on the sidewall 123B can be greater than a depth of the vertical portion 22 on the sidewall 123C as shown in FIG. 7. In some embodiments, the vertical portion 22 on the sidewall 123B extends below the line 521.

It should be noted that only the silicon portions 121 and 123 in the array region RI are depicted in FIG. 7 for a purpose of illustration. It can be understood that the residual film 20 also covers the silicon portions 122 in the peripheral region R2. In some embodiments, the residual film 20 covers horizontal portions of the substrate 12 in the peripheral region R2. In some embodiments, the residual film 20 partially covers non-horizontal portions of the substrate 12 in the peripheral region R2 depending on an angle of elevation and a depth of the non-horizontal portions. As described below, subsequent operations can be performed on the entirety of the substrate 12, and similar configurations of elements and properties of operation can be applied to the peripheral region R2.

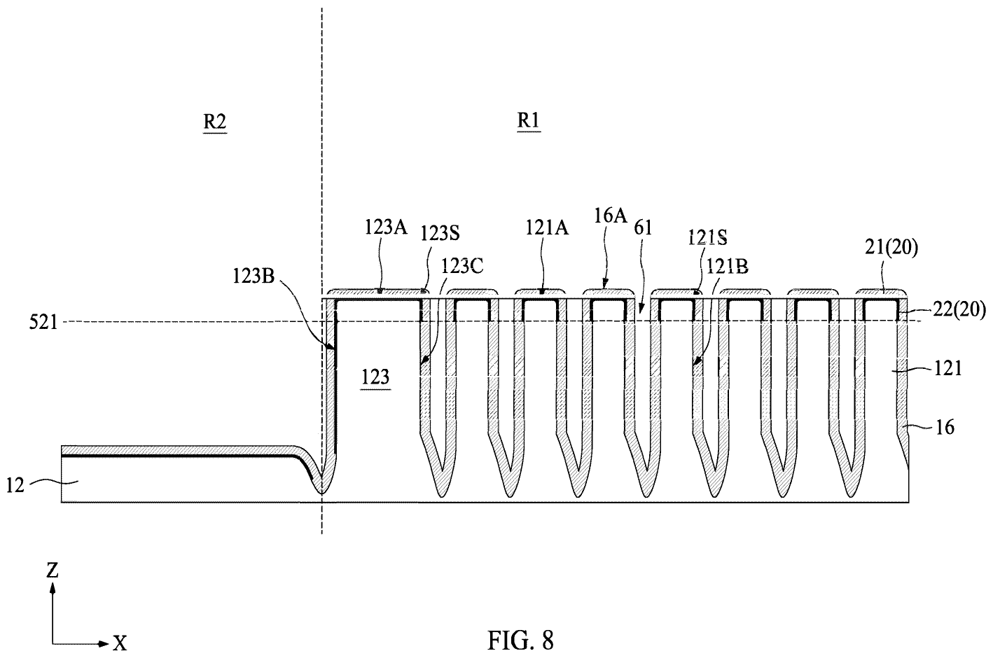

Referring to FIG. 8, an oxide layer 16 is formed over and conformal to the substrate 12. In some embodiments, a configuration of the oxide layer 16 is conformal to a configuration of the silicon portions 121, 122 and 123 of the substrate 12. In some embodiments, the oxide layer 16 is formed by a deposition. In some embodiments, the oxide layer 16 is conformal to the silicon portions 121 and 123 without filling the spaces 61 between the silicon portions 121 and between the silicon portions 121 and 123.

The silicon portions 121 and 122 may be oxidized during the formation of the oxide layer 16, and the substrate 12 exposed through the residual film 20 may be partially oxidized. However, due to the presence of the residual film 20, the top surfaces 121A and 123A and the corners 121S and 123S are protected from being oxidized during the formation of the oxide layer 16. As shown in FIG. 8, the top surfaces 121A and 123A of the silicon portions 121 and 123 remain planar, and the corners 121B and 123B of the silicon portions 121 and 123 remain sharp.

In some embodiments, the oxide layer 16 contacts the lower portions of the sidewalls 121B of the silicon portions 121 below the residual film 20. In some embodiments, the oxide layer 16 is separated from the top surface 121A and an upper portion of the sidewall 121B of the silicon portions 121. In some embodiments, the oxide layer 16 contacts the lower portion of the sidewall 123C of the silicon portion 123 below the residual film 20. In some embodiments, the oxide layer 16 is separated from the top surface 123A and from an upper portion of the sidewall 123C of the silicon portion 123 above the line 521. In some embodiments, the oxide layer 16 is separated from the sidewall 123B above and below the line 521. In some embodiments, the oxide layer 16 includes a top surface 16A. In some embodiments, the top surface 16A is a substantially planar surface. In some embodiments, a thickness of the oxide layer 16 is substantially consistent across the substrate 12. In some embodiments, the oxide layer 16 covers an entirety of the substrate 12. The respective step is illustrated as the operation S13 in the method S1 shown in FIG. 22.

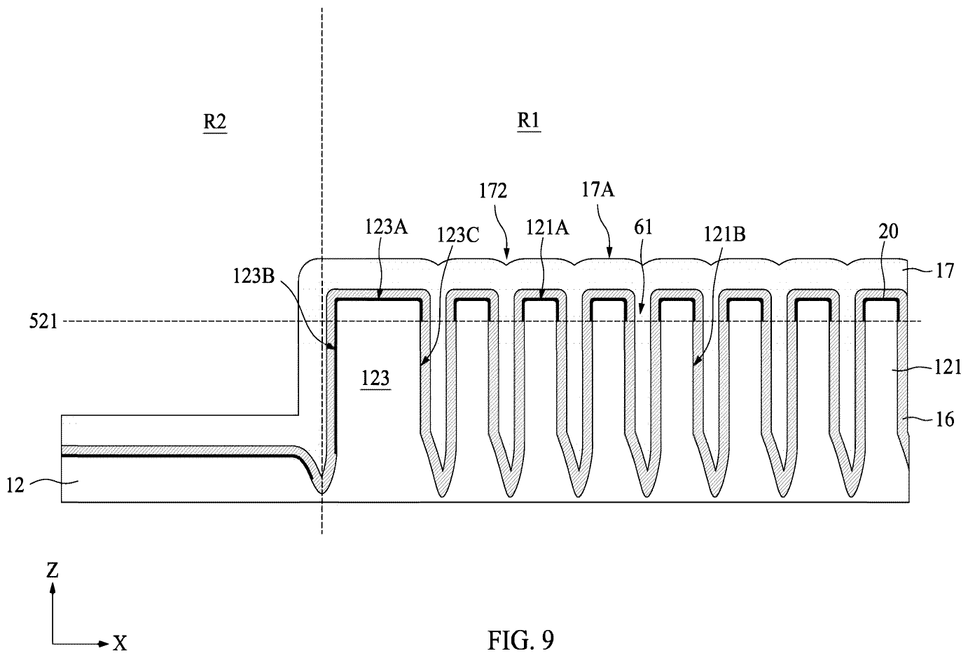

Referring to FIG. 9, a dielectric layer 17 is formed over and conformal to the substrate 12 and the silicon portions 121. In some embodiments, the dielectric layer 17 has a thickness substantially greater than a thickness of the oxide layer 16. The dielectric layer 17 can include one or more dielectric materials selected from the dielectric materials described in reference to the dielectric layers 151 and 152, and repeated description is omitted herein. In some embodiments, the dielectric layer 17 includes a dielectric material different from that of the oxide layer 16. In some embodiments, the dielectric layer 17 does not include oxide. In some embodiments, the dielectric layer 17 includes silicon nitride.

In some embodiments, the dielectric layer 17 is formed by a blanket deposition. In some embodiments, the formation of the dielectric layer 17 includes a chemical vapor deposition (CVD), a physical vapor deposition (PVD), or a combination thereof. In some embodiments, the dielectric layer 17 at least fills the spaces 61 between the silicon portions 121 and between the silicon portions 121 and 123 in the array region R1. In some embodiments, the dielectric layer 17 is disposed over the oxide layer 16 and between vertical portions of the oxide layer 16 on the sidewalls 121B and 123B of the silicon portions 121 and 123. In some embodiments, a thickness of the dielectric layer 17 is substantially greater than one-half of a distance between the silicon portions 121 for a purpose of filling the spaces 61. In some embodiments, a top surface 17A of the dielectric layer 17 is not a planar surface. In some embodiments, portions of the top surface 17A over the top surfaces 121A and 123A of the silicon portions 121 and 123 are planar. In some embodiments, the top surface 17A of the dielectric layer 17 includes a plurality of recesses 172 corresponding to positions of the spaces 61 due to a property of a deposition. The respective step is illustrated as the operation S14 in the method S1 shown in FIG. 22.

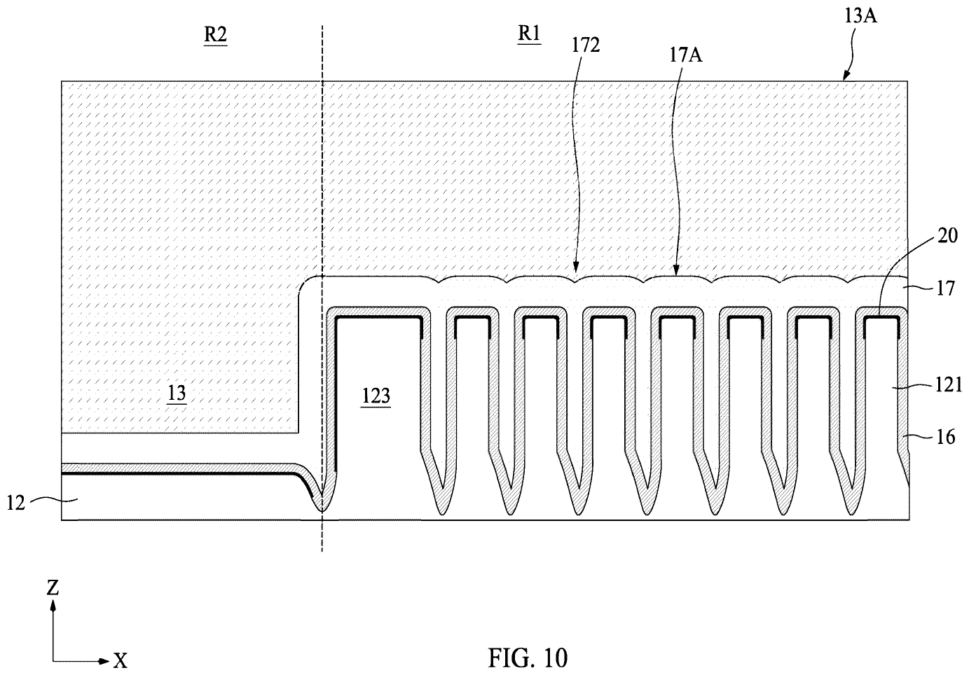

Referring to FIG. 10, a dielectric layer 13 is formed over the dielectric layer 17. In some embodiments, the dielectric layer 13 is in physical contact with the top surface 17A of the dielectric layer 17. In some embodiments, the dielectric layer 13 fills the recesses 172 of the dielectric layer 17. The dielectric layer 13 and the dielectric layer 17 are for a purpose of electrical isolation between elements. In some embodiments, the dielectric layers 13 and 17 can be considered as a dielectric structure. In some embodiments, the dielectric layers 13 and 17 can be considered as two sub-layers of a dielectric layer. In some embodiments, a top surface 13A of the dielectric layer 13 is substantially planar. In some embodiments, the dielectric layer 13 is configured to provide a planar surface for an etching operation or a polishing operation to be performed during subsequent processing in order to provide a better removal result. In some embodiments, the dielectric layer 13 includes a dielectric material, an anti-reflective coating material, an oxide-containing material, or other suitable materials. The dielectric layer 13 can include one or more dielectric materials selected from the dielectric materials described in reference to the dielectric layers 151 and 152, and repeated description is omitted herein. In some embodiments, the dielectric layer 13 includes a dielectric material different from that of the dielectric layer 17 for a purpose of etching (or polishing) selectivity. The respective step is illustrated as the operation S15 in the method S1 shown in FIG. 22.

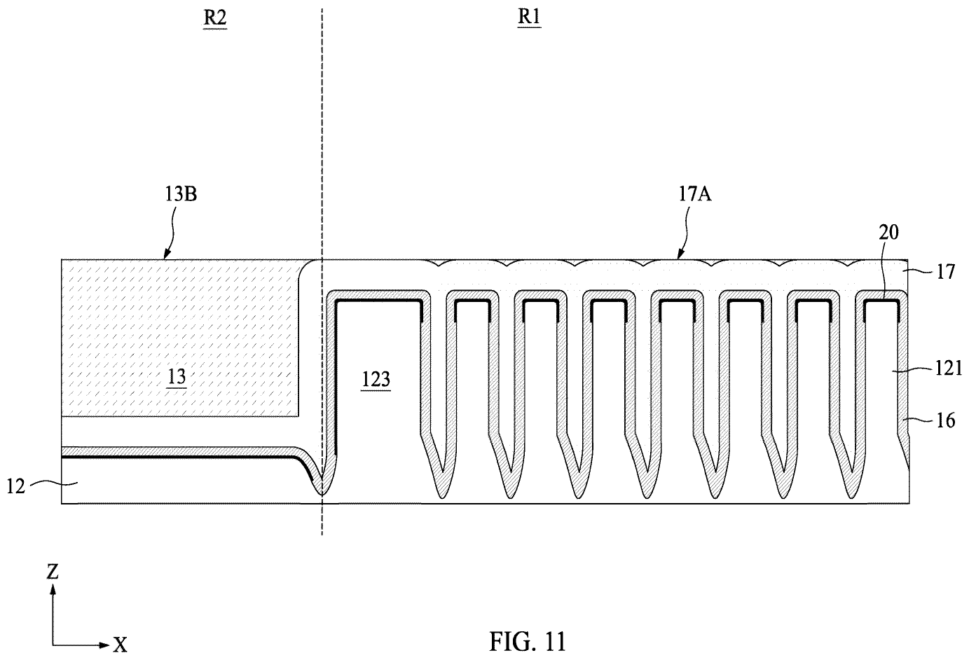

Referring to FIG. 11, a portion of the dielectric layer 13 above the dielectric layer 17 is removed. In some embodiments, a polishing operation is performed on the dielectric layer 13 and stops at the dielectric layer 17. In some embodiments, the polishing operation includes a chemical mechanical polishing (CMP) operation. In some embodiments, a slurry of the polishing operation has a high selectivity to the dielectric material of the dielectric layer 13 and a low selectivity to the dielectric material of the dielectric layer 17. In alternative embodiments, an etching operation is performed instead of the polishing operation, and the etching operation stops upon an exposure of the dielectric layer 17. In some embodiments, an etchant of the etching operation has a high selectivity to the dielectric material of the dielectric layer 13 and a low selectivity to the dielectric material of the dielectric layer 17. In some embodiments, the removal of the portion of the dielectric layer 13 above the dielectric layer 17 includes a polishing operation, an etching operation, or a combination thereof. In some embodiments, a surface 13B of the dielectric layer 13 is defined after the polishing (or etching) operation. In some embodiments, portions of the top surface 17A of the dielectric layer 17 are exposed through the dielectric layer 13. In some embodiments, the surface 13B of the dielectric layer 13 is substantially coplanar with the exposed portions of the top surface 17A of the dielectric layer 17.

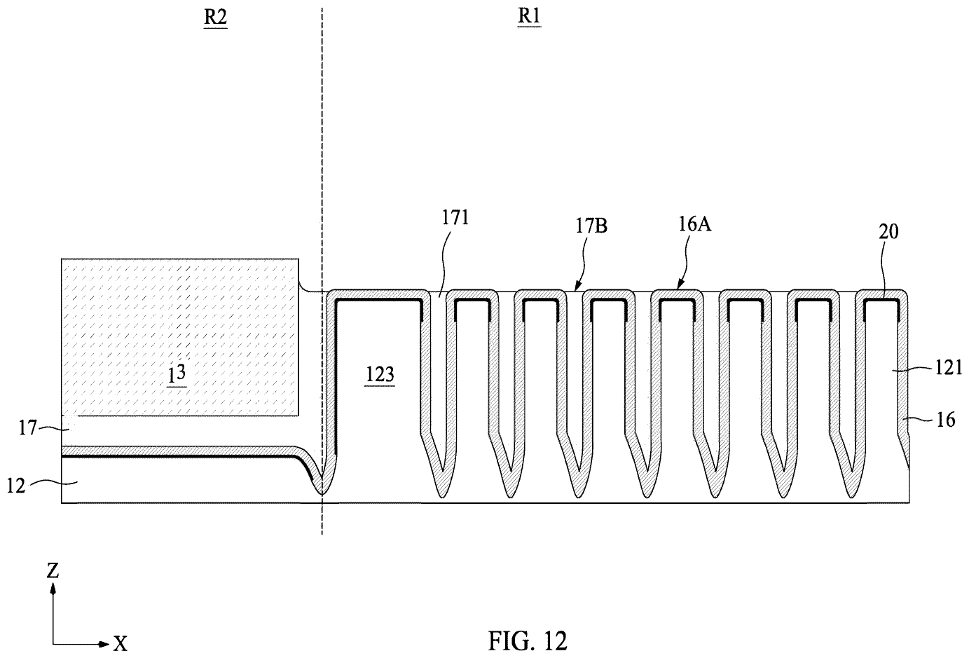

Referring to FIG. 12, portions of the dielectric layer 17 above the oxide layer 16 and the silicon portions 121 are removed. In some embodiments, a polishing operation is performed on the dielectric layer 17 and stops at the oxide layer 16. In some embodiments, the polishing operation includes a CMP operation. In some embodiments, a slurry of the polishing operation has a high selectivity to the dielectric material of the dielectric layer 17 and a low selectivity to the oxide material of the oxide layer 16. In alternative embodiments, an etching operation is performed instead of the polishing operation, and the etching operation stops upon an exposure of the oxide layer 16. In some embodiments, an etchant of the etching operation has a high selectivity to the dielectric material of the dielectric layer 17 and a low selectivity to the oxide material of the oxide layer 16. In some embodiments, the removal of the portion of the dielectric layer 17 above the oxide layer 16 includes a polishing operation, an etching operation, or a combination thereof.

In some embodiments, the dielectric layer 13 includes an oxide material similar to or same as that of the oxide layer 16. In some embodiments, the slurry of the polishing operation or the etchant of the etching operation has a low selectivity to the material of the dielectric layer 13. Therefore, the surface 13B of the dielectric layer 13 in the peripheral region R2 remains intact during and after the removal of the portion of the dielectric layer 17 above the oxide layer 16 and the silicon portions 121.

In some embodiments, a surface 17B of the dielectric layer 17 is defined after the polishing (or etching) operation. In some embodiments, a plurality of dielectric portions 171 of the dielectric layer 17 are defined between the silicon portions 121. In some embodiments, top surfaces of the dielectric portions 171 together define the surface 17B of the dielectric layer 17. The plurality of the dielectric portions 171 shown in FIG. 12 may appear connected in a 3D diagram or a top view (not shown) depending on a pattern of the silicon portions 121. Portions of the oxide layer 16 above the silicon portions 121 may be exposed through the dielectric layer 17. In some embodiments, the exposed portions of the oxide layer 16 are substantially coplanar with the surface 17B of the dielectric layer 17 (not shown). In some embodiments, the exposed portions of the oxide layer 16 protrude from the surface 17B of the dielectric layer 17 as shown in FIG. 12. The surface 17B can be substantially coplanar with or lower than the top surface 16A of the oxide layer 16 depending on the operation of the removal of the dielectric layer 17 shown in FIG. 12. In some embodiments, the surface 17B of the dielectric layer 17 is substantially coplanar with the exposed portions of the oxide layer 16 (not shown). In some embodiments, the surface 17B of the dielectric layer 17 is above the line 521.

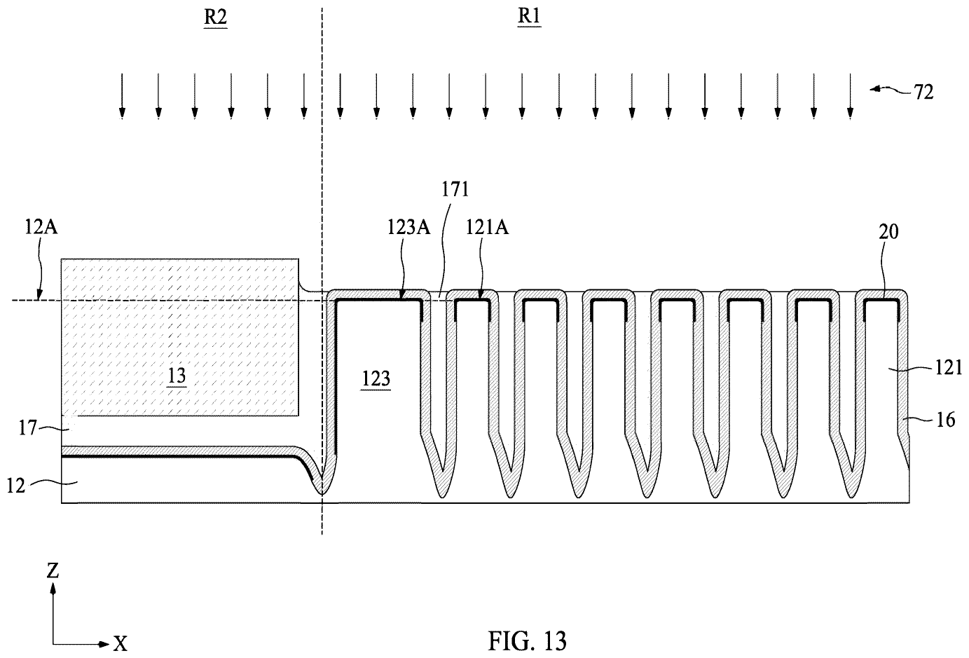

Referring to FIG. 13, a planarization 72 is performed on the dielectric layers 13, 16 and 17. The planarization 72 functions to remove portions of the dielectric layers 13, 16 and 17 above the silicon portions 121 and 123. In some embodiments, the planarization 72 includes an etching operation, such as ion beam etching, directional dry etching, reactive ion etching, solution wet etching, or a combination thereof. In some embodiments, the planarization 72 includes a low-selectivity etching operation. In some embodiments, the low-selectivity etching operation includes a low etching selectivity among materials of the dielectric layers 13, 16 and 17. In some embodiments, the planarization includes a polishing operation (e.g., a CMP operation). In some embodiments, the planarization includes a polishing operation and an etching operation. In some embodiments, the polishing operation and the etching operation include a solvent having a low selectivity to silicon. In some embodiments, the planarization 72 stops upon an exposure of the silicon portions 121 and 123. In some embodiments, the planarization 72 stops on the top surfaces 121A and 123A of the silicon portions 121 and 123 (or the top surface 12A of the substrate 12).

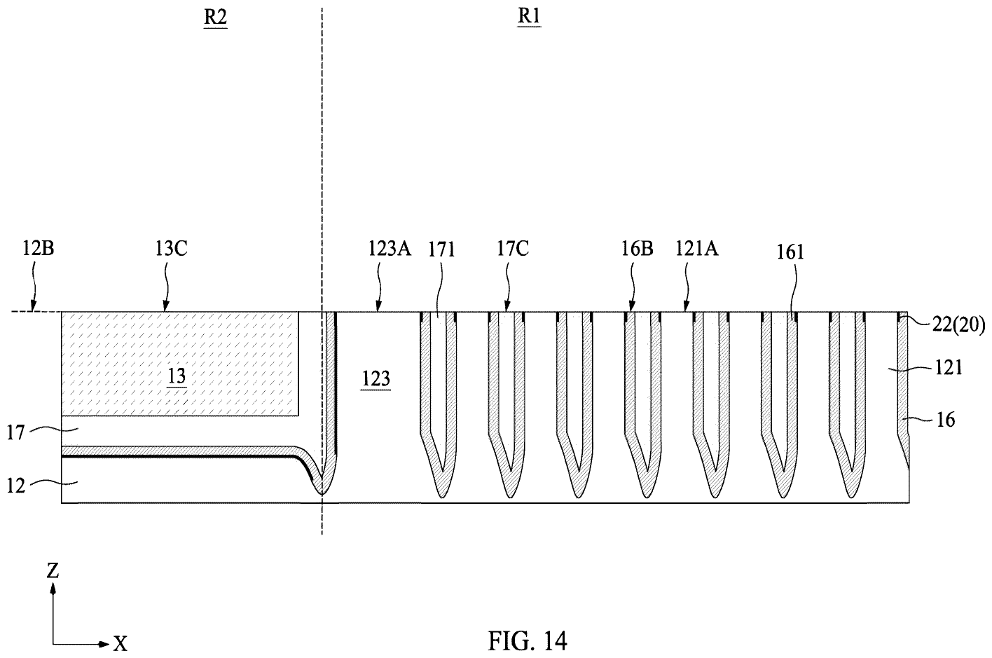

Referring to FIG. 14, FIG. 14 shows a structure resulting from the planarization 72. In some embodiments, a height of the dielectric portions 171 of the dielectric layer 17 is reduced. In some embodiments, a top surface 17C of the dielectric portions 171 is at or below an elevation of the line 521. The plurality of the dielectric portions 171 shown in FIG. 14 may appear connected in a 3D diagram or from a top view (not shown) depending on a pattern of the silicon portions 121. In some embodiments, portions of the oxide layer 16 above the line 521 are removed by the planarization 72 to form a plurality of oxide portions 161 surrounding each of the silicon portions 121. The plurality of the oxide portions 161 shown in FIG. 14 may appear connected in a 3D diagram or from a top-view perspective (not shown) depending on the pattern of the silicon portions 121.

In some embodiments, a top surface 16B of the dielectric layer 16 is defined after the planarization 72 in FIG. 13. In some embodiments, the top surface 16B is defined by top surfaces of the oxide portions 161. In some embodiments, the top surfaces 121A and 123A of the silicon portions 121 and 123 (or the top surface 12A of the substrate 12) are exposed after the planarization 72. In some embodiments, a top surface 13C of the dielectric layer 13 is defined in the peripheral region R2 after the planarization 72 in FIG. 13.

In some embodiments, the top surface 13C of the dielectric layer 13, the top surfaces 121A of the silicon portions 121, the top surface 123A of the silicon portion 123, the top surface 16B of the oxide portions 161, and the top surface 17C of the dielectric portions 171 are substantially coplanar. The top surface 13C of the dielectric layer 13, the top surfaces 121A of the silicon portions 121, the top surface 123A of the silicon portion 123, the top surface 16B of the oxide portions 161, and the top surface 17C of the dielectric portions 171 together define a surface 12B, which is a top surface of the intermediate structure shown in FIG. 14. In some embodiments, the surface 12B is a planar surface. In some embodiments, the surface 12B is at a horizontal level substantially even with a horizontal level of the surface 12A shown in FIG. 13. In some embodiments, the surface 12B is substantially lower than the surface 12A to ensure that the oxide layer 16 above the silicon portions 121 is entirely removed.

It should be noted that the horizontal portions 21 of the residual film 20 shown in FIG. 7 may be also removed by the planarization 72 shown in FIG. 13 even if the etchant/slurry is not highly selective to nitrogen. In some embodiments, the vertical portions 22 of the residual film 20 remain in place. The vertical portions 22 may be partially or entirely remaining depending on the planarization 72.

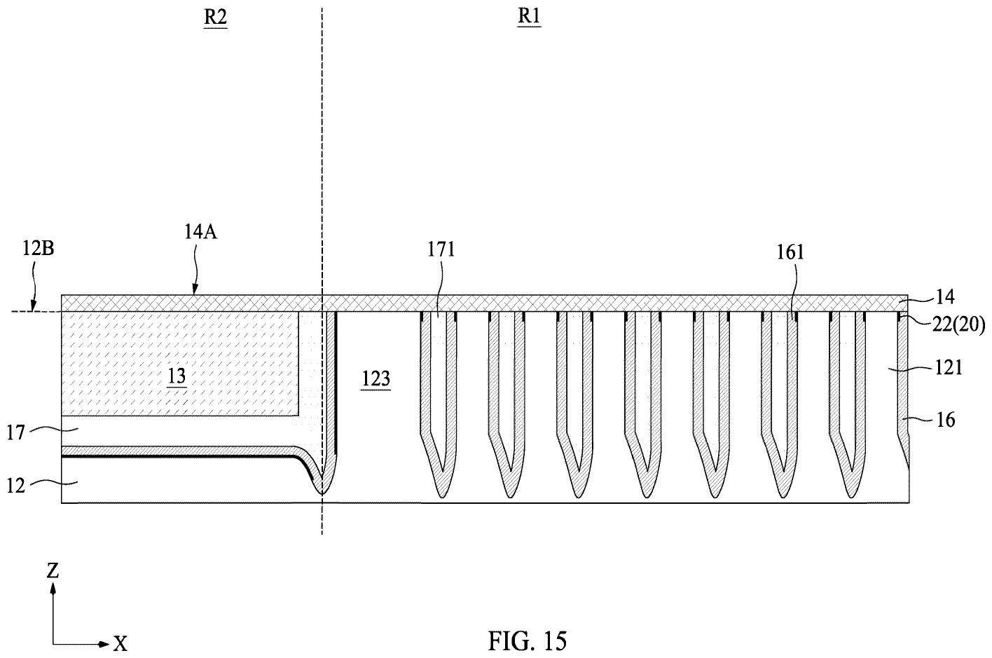

Referring to FIG. 15, an insulating layer 14 may be formed on the surface 12B over the dielectric portions 171, the oxide portions 161, the silicon portions 121, and the dielectric layer 13. The insulating layer 14 includes one or more dielectric materials. In some embodiments, the insulating layer 14 is referred to as a dielectric layer 14. In some embodiments, the insulating layer 14 contacts the dielectric portions 171, the oxide portions 161, the silicon portions 121, and the dielectric layer 13. In some embodiments, the insulating layer 14 contacts the vertical portions 22 of the residual film 20. In some embodiments, the insulating layer 14 is formed in the array region R1 and the peripheral region R2. Since the surface 12B is a substantially planar surface, a top surface 14A of the insulating layer 14 formed on the surface 12B is a substantially planar surface. In some embodiments, the insulating layer 14 includes nitride, such as silicon nitride. In some embodiments, the insulating layer 14 is formed using a CVD process, a PVD process, or any other suitable process. In some embodiments, a thickness of the insulating layer 14 is in a range of 5 to 30 nm.

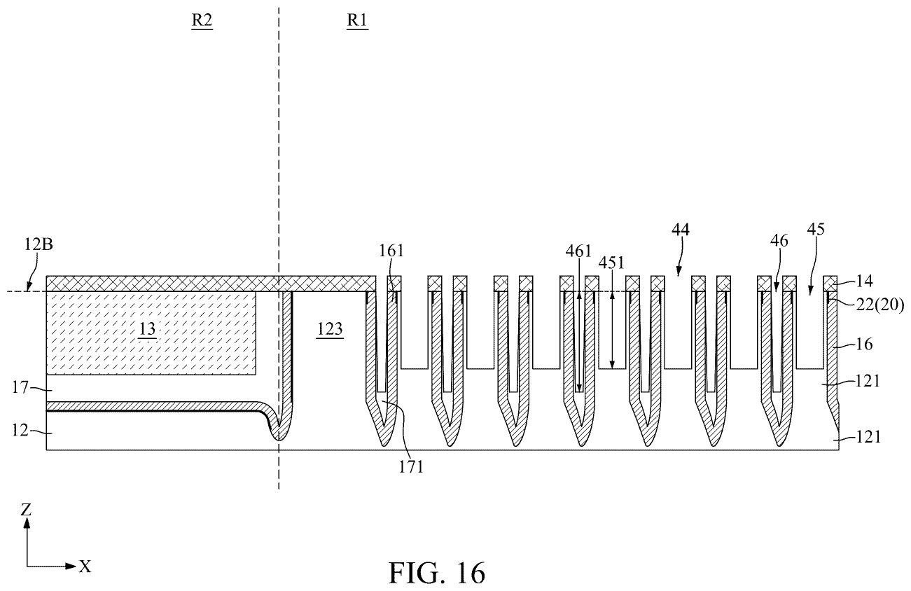

Referring to FIG. 16, a patterning operation is performed. Portions of the silicon portions 121 in the array region R1 and portions of the dielectric portions 171 are removed by the patterning operation. The patterning operation can include one or multiple steps, and the insulating layer 14, the dielectric layer 17 and the silicon portions 121 can be patterned concurrently by one etching step or sequentially by different etching steps depending on the materials of the insulating layer 14, the dielectric layer 17 and the silicon portions 121. In some embodiments, a plurality of openings 44, a plurality of trenches 45 and a plurality of trenches 46 are formed by the patterning operation. In some embodiments, each of the openings 44 penetrates and is surrounded by the insulating layer 14. In some embodiments, the openings 44 are defined by the insulating layer 14. In some embodiments, the trenches 45 are defined by the silicon portions 121 of the substrate 12. In some embodiments, each of the trenches 45 is formed in a silicon portion 121. In some embodiments, the trenches 46 are defined by the dielectric portions 171. In some embodiments, each of the trenches 46 is formed in a dielectric portion 171. In some embodiments, a trench 45 is surrounded by an oxide portion 161. In some embodiments, the trench 45 is separated from adjacent silicon portions 121 by the oxide portions 161.

Depths of the trenches 45 may be substantially equal, and depths of the trenches 46 may be substantially equal. In some embodiments, a depth 451 of the trench 45 measured from the surface 12B is different from a depth 461 of the trench 46 measured from the surface 12B. In some embodiments, the depth 451 of the trench 45 is substantially less than the depth 461 of the trench 46. In some embodiments, a difference between the depth 451 and the depth 461 is due to different etching rates on different materials during one etching step of the patterning operation. In some embodiments, the trenches 45 and the trenches 46 are formed by different etching steps, and the depths 451 and the depths 461 are controlled to be different for a purpose of formation of WL metals performed during subsequent processing. The respective step is illustrated as the operation S16 in the method S1 shown in FIG. 22.

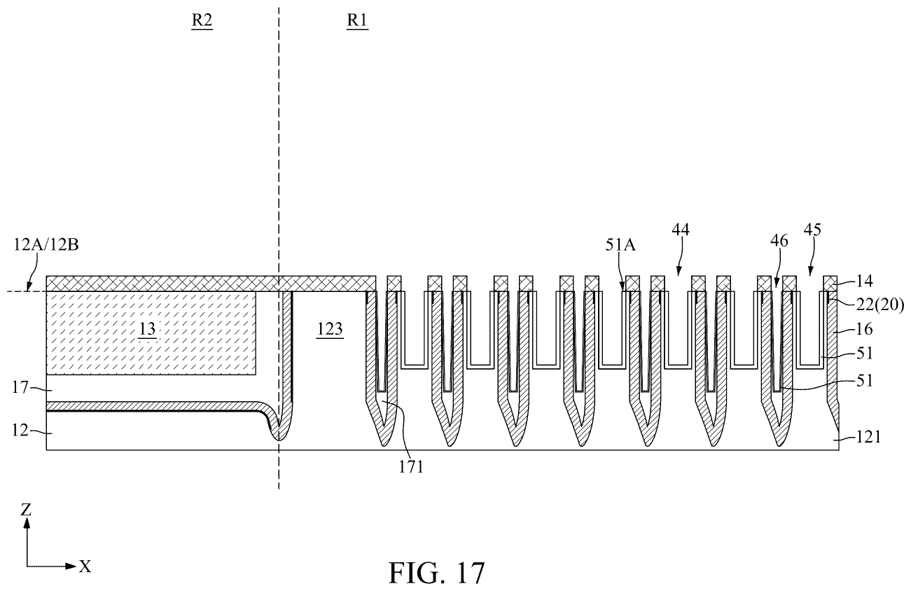

Referring to FIG. 17, a dielectric layer 51 lining each of the trenches 45 is formed. In some embodiments, the dielectric layer 51 is formed only in the trenches 45. In some embodiments, the dielectric layer 51 contacts the silicon portions 121. In some embodiments, the dielectric layer 51 is formed by a thermal oxidation. In some embodiments, the dielectric layer 51 includes silicon oxide. In some embodiments, the dielectric layer 51 is separated from adjacent vertical portions 22 of the residual film 20 by the silicon portion 121. In some embodiments, a top surface 51A of the dielectric layer 51 is substantially coplanar with the top surface 121A of the pillars 121.

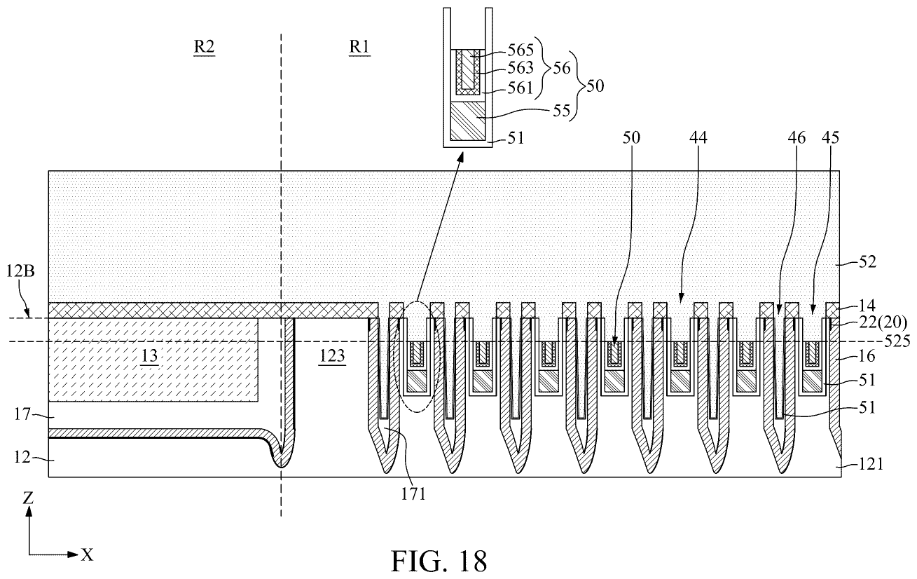

Referring to FIG. 18, a plurality of word lines 50 are formed in the trenches 45. That is, each of the word lines 50 is formed in the pillar-like silicon portion 121. Each of the word lines 50 includes the dielectric layer 51, a lower electrode structure 55, and an upper electrode structure 56. In some embodiments, a dielectric layer 51 may be formed in each of the trenches 45, and a lower electrode structure 55 may be formed in a lower portion of each of the trenches 45 in which the dielectric layer 51 is formed. In other words, the lower electrode structure 55 is formed on the dielectric layer 51. The upper electrode structure 56 is formed on the lower electrode structure 55. In some embodiments, the upper electrode structure 56 includes a preliminary source layer 561, a preliminary work-function adjustment layer 563, and a conductive layer 565. The preliminary source layer 561 is formed on each lower electrode structure 55 and a sidewall of each dielectric layer 51. The preliminary source layer 561 may be formed using a chemical vapor deposition (CVD) process. The preliminary source layer 561 may include a work-function adjustment element or a compound of a work-function adjustment element. For example, the work-function adjustment element may include a metal such as lanthanum, strontium, antimony, yttrium, aluminum, tantalum, hafnium, iridium, zirconium, or magnesium. The preliminary work-function adjustment layer 563 may be formed to conformally cover the preliminary source layer 561. The preliminary work-function adjustment layer 563 may be formed using a chemical vapor deposition (CND) process. The conductive layer 565 may fill remaining portions of the trenches 45 and may cover substantially an entire top surface of the preliminary work-function adjustment layer 563. For example, the conductive layer 565 may cover substantially an entire surface of the preliminary work-function adjustment layer 563 opposite the preliminary source layer 561. The conductive layer 565 may include a low-resistance material having a resistance less than that of the preliminary work-function adjustment layer 563. For example, the conductive layer 565 may include a metal such as tungsten, titanium, or tantalum. The conductive layer 565 including a conductive material may be formed on the preliminary work-function adjustment layer 563 including the metal or the metal nitride. In some embodiments, the conductive layer 565, the preliminary work-function adjustment layer 563, and the preliminary source layer 561 may be etched to form the upper electrode structure 56 in each of the trenches 45. A plurality of word lines 50 are formed in the trenches 45. The etching process may be continuously performed until the preliminary source layer 561, the preliminary work-function adjustment layer 563 and the conductive layer 565 have desired thicknesses in the trenches 45. Top surfaces of the source layer 561, the work-function adjustment layer 563 and the conductive layer 565 formed by the etching process may be disposed at a same level.

Subsequently, a conductive material 52 is formed over the substrate 12, the word line 50, and the patterned insulating layer 14. The conductive material 52 may fill the openings 44 and the trenches 45 and 46. In some embodiments, the conductive material 52 fills an entirety of the trenches 45 and 46. In some embodiments, the conductive material 52 is formed by a deposition. In some embodiments, the conductive material 52 includes aluminum (Al), copper (Cu), tungsten (W), titanium (Ti), tantalum (Ta), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru), titanium silicon nitride (TiSiN), other suitable materials, or a combination thereof. In some embodiments, the conductive material 52 is W, TiN, or a combination thereof.

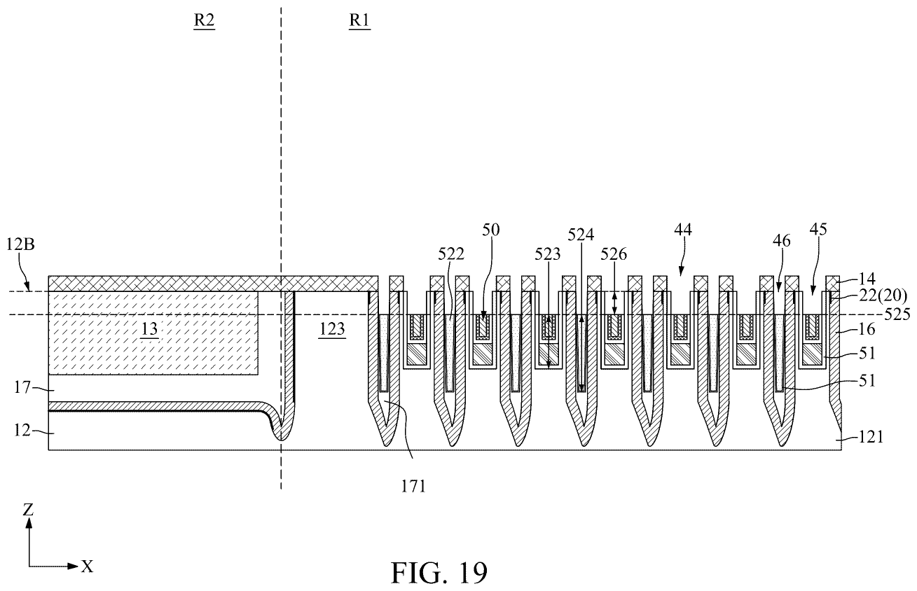

Referring to FIG. 19, an upper portion of the conductive material 52 is removed. In some embodiments, a plurality of contacts 522 are formed in the trenches 46. In some embodiments, the word lines 50 and the contacts 522 are referred to as WL metals. In some embodiments, the word lines 50 and the contacts 522 are alternately arranged.

Referring back to FIG. 18, a dashed line labeled 525 indicates a designed top surface of the word lines 50 and the contacts 522 shown in FIG. 19. For a purpose of electrical connection, the designed top surface 525 should be lower than the surface 12B (or lower than the top surface 51A of the dielectric layer 51 shown in FIG. 17). In other words, a distance 526 measured from the surface 12B to the designed top surface 525 should be greater than zero. However, a range of the distance 526 can be adjusted according to different applications, and the distance 526 is not limited herein. In addition, it should be noted that the figures are for a purpose of illustration, and tops of different word lines 50 and/or contacts 522 can be at roughly a same elevation but not necessarily at a same horizontal level. In some embodiments, a height 523 of the word lines 50 and a height 524 of the contacts 522 from the designed top surface 525 are different due to different depths 451 and 461 of the trenches 45 and 46 shown in FIG. 14. In some embodiments, the height 523 of the word lines 50 is substantially less than the height 524 of the contacts 522 from the designed top surface 525. That is, a top surface of the plurality of word lines 50 is lower than the top surfaces of the pillars 121. The respective step is illustrated as the operation S17 in the method S1 shown in FIG. 22.

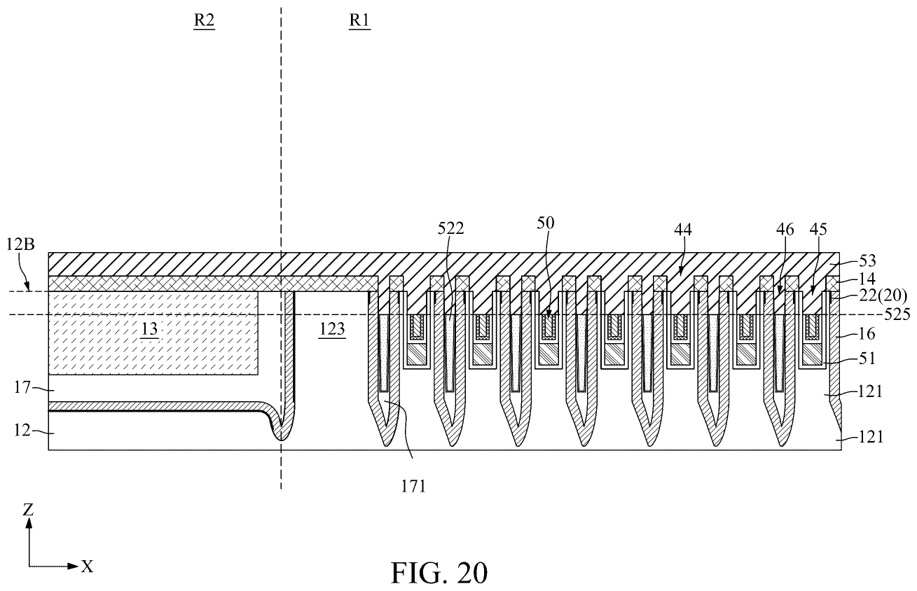

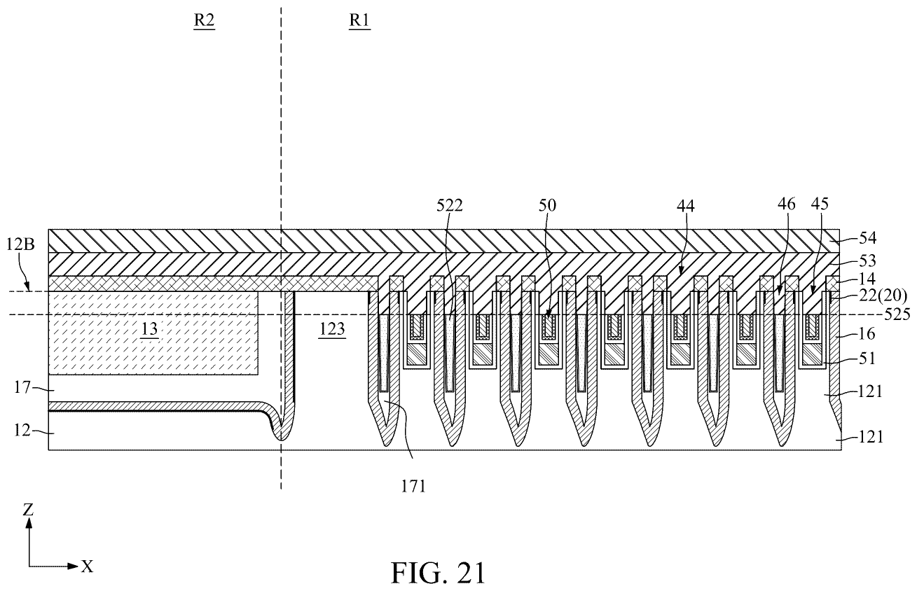

Referring to FIGS. 20 and 21, a first dielectric layer 53 and a second dielectric layer 54 are sequentially formed over the substrate 12. Each of the first dielectric layer 53 and the second dielectric layer 54 may cover the word lines 50 and the contacts 522 and the patterned insulating layer 14. In some embodiments, the first dielectric layer 53 and the second dielectric layer 54 include different dielectric materials. In some embodiments, the first dielectric layer 53 includes nitride (e.g., silicon nitride), and the second dielectric layer 54 includes oxide (e.g., silicon oxide). In some embodiments, the first dielectric layer 53 fills the trenches 45 above the word lines 50. In some embodiments, the first dielectric layer 53 fills the trenches 46 above the contacts 522. In some embodiments, the first dielectric layer 53 fills the openings 44. In some embodiments, the first dielectric layer 53 covers an entirety of the patterned insulating layer 14. In some embodiments, the second dielectric layer 54 covers an entirety of the first dielectric layer 53. The semiconductor structure 10 is thereby formed.

Bit line (BL) metals may be formed over the semiconductor structure 10 shown in FIG. 21. In some embodiments, landing pads are formed after the BL metals to electrically connect with the silicon portions 121 in the array region R1. The present disclosure provides the silicon portions 121 having planar top surfaces, and thus issues of electrical disconnection or high electrical resistance between a silicon pillar and a landing pad resulting from rounding of the silicon pillar can be prevented. A performance and a product yield of a device formed according to the method can be thereby improved.

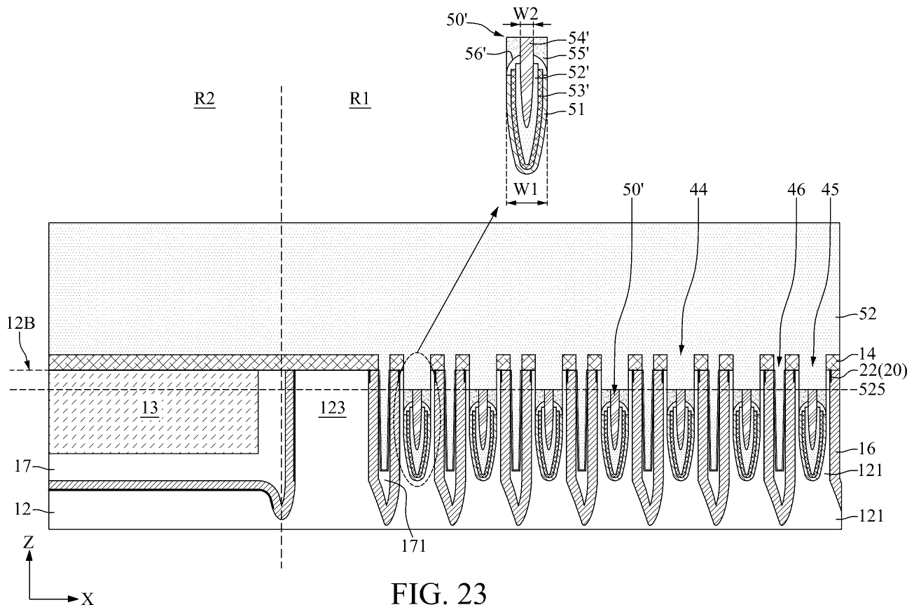

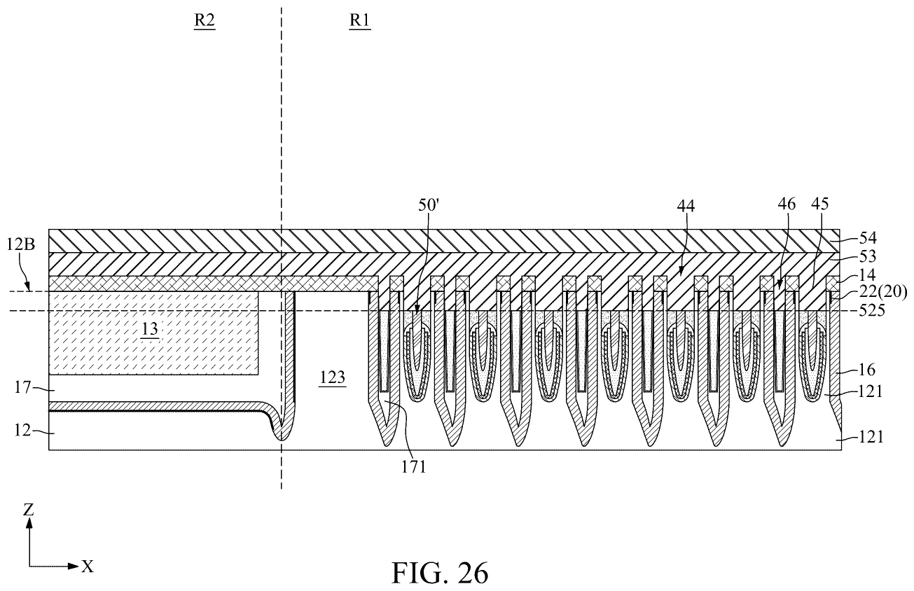

FIGS. 23 to 26 are cross-sectional diagrams along a line A-A′ shown in FIG. 2 of intermediate stages in the formation of the semiconductor structure in accordance with some embodiments of the present disclosure. The structures of FIGS. 23 to 26 are similar to the structures of FIGS. 18 to 21, except for the word lines. The word lines in FIGS. 23 to 26 are indicated by the numeral 50′.

FIG. 27 is a flow diagram illustrating a method S2 for manufacturing a semiconductor device in accordance with some embodiments of the present disclosure. The method S2 includes a number of operations (S21, S22, S23, S24, S25, S26 and S27) and the description and illustration are not deemed as a limitation to the sequence of the operations. In the operation S21, a substrate is provided, wherein the substrate includes a plurality of pillars, and a top surface of each of the plurality of pillars is a substantially planar surface. In the operation S22, a nitrogen treatment is performed on the pillars. In the operation S23, an oxide layer is formed over the substrate conformal to the plurality of pillars. In the operation S24, a first dielectric layer is formed over the substrate and among the pillars. In the operation S25, a second dielectric layer is formed over the plurality of pillars. In the operation S26, a plurality of first trenches are formed in the plurality of pillars and a plurality of second trenches are formed in the first dielectric layer among the pillars. In the operation S27, the plurality of first trenches are filled with a conductive material to form a plurality of word lines, wherein each of the word lines includes a word line layer disposed in the substrate and surrounded by a dielectric liner, and an insulative plug disposed in the substrate and extending into the word line layer. It should be noted that the operations of the method S2 may be rearranged or otherwise modified within the scope of the various aspects. Additional processes may be provided before, during, and after the method S2, and some other processes may be only briefly described herein. Thus, other implementations are possible within the scope of the various aspects described herein.

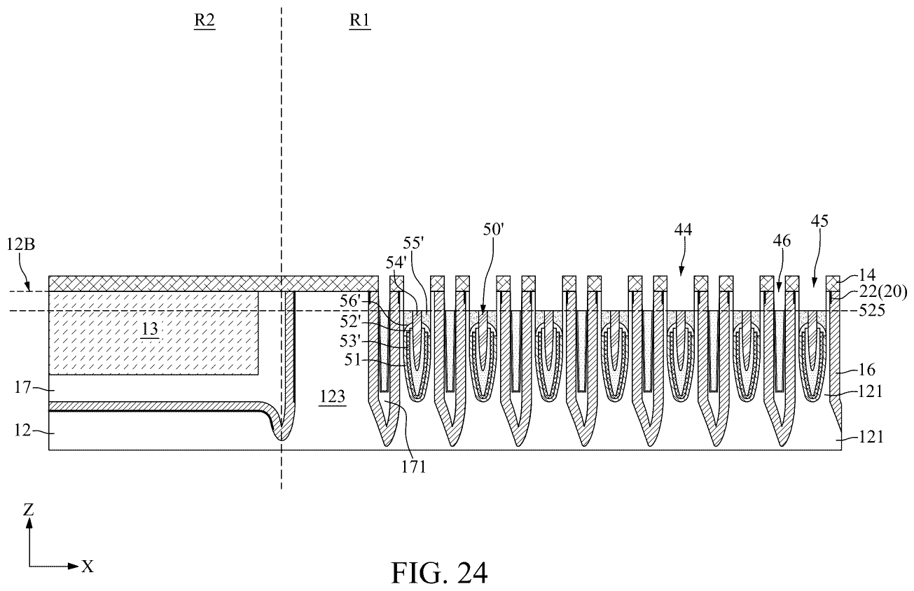

As shown in FIG. 24, each of the word lines 50′ includes a word line layer 52′ disposed in the substrate 12 and surrounded by the dielectric liner 51, and an insulative plug 54′ disposed in the substrate 12 and extending into the word line layer 52′. The dielectric liners 51, between the substrate 12 and the word line layers 52′, are employed to prevent junction leakage. The word line 50′ further includes an isolation layer 55′ disposed in the substrate 12 and employed to cap the word line layers 52′. With high integration of semiconductor devices, a distance between the word line layers 52′ may be reduced. This may increase parasitic capacitance between the word line layers 52′, and the performance of the semiconductor device may be degraded. To mitigate such issue, a plurality of voids 56′ that typically hold air, which has a dielectric constant or k value of about 1, can be introduced into the isolation layer 55′ to reduce parasitic capacitance. Thus, a leakage current in the highly-integrated semiconductor device may be further reduced, thereby improving the performance of the semiconductor device.

In some embodiments, the void 56′, buried in the isolation layer 55′, extends around the perimeter of the insulative plug 54′. In some embodiments, the void 56′ can separate at least a portion of the word line layer 52′ from the isolation layer 55′. In some embodiments, the isolation layer 55′ capping the word line layer 52′ may introduce a plurality of voids 56′ having a low dielectric constant to reduce the parasitic capacitances. In some embodiments, the insulative plug 54′ and the isolation layer 55′ can include a same dielectric material if one or more voids 56′ are buried in the isolation layer 55′. In alternative embodiments, the insulative plug 54′ and the isolation layer 55′ may include different dielectric materials; the isolation layer 55′ can have a first dielectric constant, and the insulative plug 54′ can have a second dielectric constant less than the first dielectric constant to further reduce the parasitic capacitance.

In some embodiments, the word line layer 52′ and the insulative plug 54′ embedded in the word line layer 52′ are concentric. In some embodiments, the word line layer 52′ has a first width W1 (e.g., a top or maximum width), and the insulative plug 54′ has a second width W2 (e.g., a top or maximum width) less than the first width W1. In some embodiments, the first width W1 and the second width W2 gradually decrease at positions of increasing distance from the top surface 12B of the substrate 12. In some embodiments, the word line 50′ may also include a plurality of diffusion barrier liners 53′ disposed between the dielectric liners 51 and the word line layers 52′. The diffusion barrier liners 53′ are employed to prevent the word line layers 52′ from flaking or spalling from the dielectric liners 51. The respective step is illustrated as the operation S27 in the method S2 shown in FIG. 27.

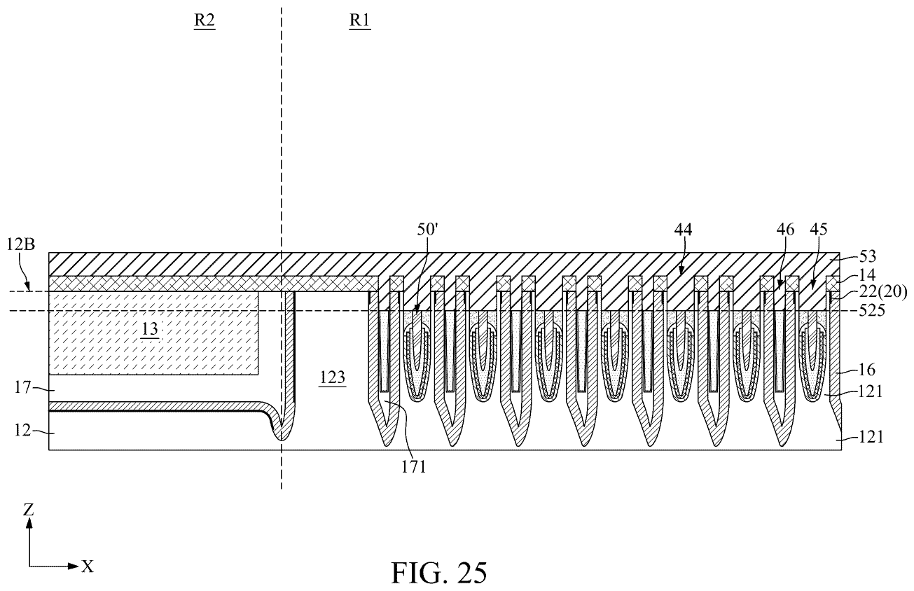

The operations of FIGS. 25 to 27 are same as the operations of FIGS. 19 to 21, and repeated descriptions are omitted herein.

The present disclosure provides a manufacturing method and a semiconductor structure thereof. The manufacturing method of the present disclosure is able to provide a planar surface of a silicon pillar so as to avoid issues of electrical disconnection and high electrical resistance. A performance and a product yield of a device formed according to the method can be thereby improved.

One aspect of the present disclosure provides a semiconductor structure. The semiconductor structure includes a substrate, including a plurality of pillars in an array region of the substrate, wherein a top surface of each of the plurality of pillars is a substantially planar surface; a residual film, partially disposed on sidewalls of the pillars proximal to the top surfaces of the pillars; an oxide layer, surrounding each of the pillars; a plurality of word lines, disposed in the pillars respectively; and a plurality of contacts, disposed between two adjacent pillars respectively; wherein each of the word lines includes a dielectric layer, a lower electrode structure, and an upper electrode structure, and wherein the dielectric layer is disposed in the pillar, a lower electrode structure is disposed on the dielectric layer, and an upper electrode structure is disposed on the lower electrode structure.

Another aspect of the present disclosure provides a semiconductor structure. The semiconductor structure includes a substrate, including a plurality of pillars in an array region of the substrate, wherein a top surface of each of the plurality of pillars is a substantially planar surface; a residual film, partially disposed on sidewalls of the pillars proximal to the top surfaces of the pillars; an oxide layer, surrounding each of the pillars; a plurality of word lines, disposed in the pillars respectively; and a plurality of contacts, disposed between two adjacent pillars respectively; wherein the word line includes a word line layer disposed in the substrate and surrounded by a dielectric liner disposed in the substrate and an insulative plug extending into the word line layer.

Another aspect of the present disclosure provides a method of manufacturing a semiconductor structure. The method includes providing a substrate, wherein the substrate includes a plurality of pillars, and a top surface of each of the plurality of pillars is a substantially planar surface; performing a nitrogen treatment on the pillars; forming an oxide layer over the substrate conformal to the plurality of pillars; forming a first dielectric layer among the pillars; forming a second dielectric layer over the plurality of pillars, wherein a top surface of the second dielectric layer is a substantially planar surface; forming a plurality of first trenches in the plurality of pillars and a plurality of second trenches in the first dielectric layer among the pillars; and forming a word line in each of the first trenches, wherein each of the word lines includes a dielectric layer, a lower electrode structure, and an upper electrode structure, wherein a dielectric layer is disposed in the pillar, a lower electrode structure is disposed on the dielectric layer, and an upper electrode structure is disposed on the lower electrode structure.

Another aspect of the present disclosure provides a method of manufacturing a semiconductor structure. The method includes providing a substrate, wherein the substrate includes a plurality of pillars, and a top surface of each of the plurality of pillars is a substantially planar surface; performing a nitrogen treatment on the pillars; forming an oxide layer over the substrate conformal to the plurality of pillars; forming a first dielectric layer among the pillars; forming a second dielectric layer over the plurality of pillars, wherein a top surface of the second dielectric layer is a substantially planar surface; forming a plurality of first trenches in the plurality of pillars and a plurality of second trenches in the first dielectric layer among the pillars; and forming a word line in each of the first trenches, wherein each of the word lines includes a word line layer disposed in the substrate and surrounded by a dielectric liner and an insulative plug disposed in the substrate and extending into the word line layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor structure, comprising:
a substrate, including a plurality of pillars in an array region of the substrate, wherein a top surface of each of the plurality of pillars is a substantially planar surface;
a residual film, partially disposed on sidewalls of the pillars proximal to the top surfaces of the pillars;
an oxide layer, surrounding each of the pillars;
a plurality of word lines, respectively disposed in the pillars; and
a plurality of contacts, respectively disposed between two adjacent pillars;
wherein the word line includes a word line layer disposed in the substrate and surrounded by a dielectric liner, and an insulative plug disposed in the substrate and extending into the word line layer.

2. The semiconductor structure of claim 1, wherein the word line further includes an isolation layer disposed in the substrate and employed to cap the word line layer.

3. The semiconductor structure of claim 2, wherein a plurality of voids are introduced into the isolation layers.

4. The semiconductor structure of claim 3, wherein the void is buried in the isolation layer and extends around a perimeter of the insulative plug to separate at least a portion of the word line layer from the isolation layer.

5. The semiconductor structure of claim 4, wherein the word line layer and the insulative plug embedded in the word line layer are concentric.

6. The semiconductor structure of claim 1, wherein the word line layer has a first width, and the insulative plug has a second width less than the first width.

7. The semiconductor structure of claim 6, wherein the first width and the second width gradually decrease at positions of increasing distance from a top surface of the substrate.

8. The semiconductor structure of claim 1, wherein the word line further includes a diffusion barrier liner disposed between the dielectric liner and the word line layer.

9. The semiconductor structure of claim 1, wherein the word lines and the contacts are alternately arranged.

10. The semiconductor structure of claim 1, wherein the substrate includes a peripheral region surrounding the array region, and the residual film is disposed in the peripheral region.

11. The semiconductor structure of claim 1, wherein a nitrogen treatment is performed on the substrate.

12. The semiconductor structure of claim 11, wherein the nitrogen treatment is to provide nitrogen to the substrate.

13. The semiconductor structure of claim 1, wherein the residual film caps each of the pillars.
